(19) United States
(12) Patent Application Publication
(10) Pub. No.: US 2024/0421254 A1
(43) Pub. Date: Dec. 19, 2024

(54) LIGHT EMITTING DIODE AND LIGHT EMITTING DEVICE HAVING THE SAME

(71) Applicant: TIANJIN SANAN OPTOELECTRONICS CO., LTD., Tianjin (CN)

(72) Inventors: Zhiming LI, Xiamen (CN); Chi SHEN, Xiamen (CN); Bing-Yang CHEN, Xiamen (CN); Jiansheng QUE, Xiamen (CN)

(21) Appl. No.: 18/819,287

(22) Filed: Aug. 29, 2024

Related U.S. Application Data
(63) Continuation-in-part of application No. PCT/CN2022/097762, filed on Jun. 9, 2022.

(51) Int. Cl. H01L 33/24; H01L 33/06; H01L 33/12; H01L 33/32

(52) U.S. Cl. CPC H01L 33/24; H01L 33/12; H01L 33/325; H01L 33/06

(57) ABSTRACT

A light emitting diode includes an epitaxial semiconductor layer including an N-type nitride layer, a v-pit emergence layer, a strain adjustment layer, an active layer, and a P-type nitride layer that are sequentially stacked in that order. The active layer has a plurality of barrier layers and a plurality of well layers that are alternatively stacked. The epitaxial semiconductor layer includes a v-pit. The v-pit has an opening that is located at a topmost one of the barrier layers of the active layer, and has a width that is greater than 260 nm. The v-pit emergence layer is doped with carbon (C) at a doping concentration that is no less than 7×1016/cm3. A light emitting device includes the light emitting diode.

### CROSS-REFERENCE TO RELATED APPLICATION

This application is a continuation-in-part (CIP) of International Application No. PCT/CN2022/097762, filed on Jun. 9, 2022, and incorporated by reference herein in its entirety.

### FIELD

The disclosure relates to a light emitting diode, and more particularly to a light emitting diode and a light emitting device including the same.

### BACKGROUND

Light emitting diodes (LEDs) have received wide application in lighting appliances and have been widely used in lighting, backlighting, vehicle lighting, decorative lighting, and the lighting of various electronic products. The efficiency of light emitting diodes primarily depends on two factors: one is electron and hole recombination efficiency in an active layer of the light emitting diode which is known as the internal quantum efficiency; the other factor is light extraction efficiency. A P-type dopant such as Mg may require a relatively higher activation energy in nitride materials, and the holes may have a higher effective mass which causes lower hole injection efficiency.

In recent years, numerous research have shown that forming v-pits in a quantum well layer of nitride based LEDs greatly increases hole injection efficiency, and improves internal quantum efficiency. Currently, v-pit formation techniques have already been utilized for mass production of nitride based LEDs. However, hole injection also occurs in other areas of the nitride based LED on a c-plane of the crystal lattice where there is no v-pit formation, and hole injection efficiency in these areas is poor (no v pits are formed in these areas). Therefore, the improvement of photoelectric characteristics of nitride based LEDs is limited. For example, such nitride based LEDs have a relatively larger forward operating voltage Vf1, and suffers from efficiency droop under large currents. Therefore, how to improve hole injection efficiency in the areas of nitride based LEDs without the v-pits is a technical problem which requires a solution.

### SUMMARY

Therefore, an object of the disclosure is to provide a light emitting diode and a light emitting device that can alleviate at least one of the drawbacks of the prior art.

According a first aspect of the disclosure, the light emitting diode includes an epitaxial semiconductor layer. The epitaxial semiconductor layer includes an N-type nitride layer, a v-pit emergence layer, a strain adjustment layer, an active layer, and a P-type nitride layer that are sequentially stacked in that order. The active layer has a plurality of barrier layers and a plurality of well layers that are alternatively stacked together from bottom up. The well layers have a smaller band gap than that of the barrier layers. The epitaxial semiconductor layer further includes at least one v-pit. Each of the v-pit emergence layer and the strain adjustment layer includes indium, and an indium (In) content of the strain adjustment layer is higher than an indium (In) content of the v-pit emergence layer. The at least one v-pit has an opening that is located at a topmost one of the barrier layers of the active layer, and has a width that is greater than 260 nm. The v-pit emergence layer is doped with carbon (C) at a doping concentration that is no less than 7×10¹⁶/cm³.

According to another aspect of the disclosure the light emitting device includes the light emitting diode in the first aspect.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a first embodiment a light emitting diode according to the present disclosure.

FIG. 2 is a schematic top view illustrating the first embodiment.

FIG. 3 is a fragmentary schematic cross-sectional view illustrating the first embodiment.

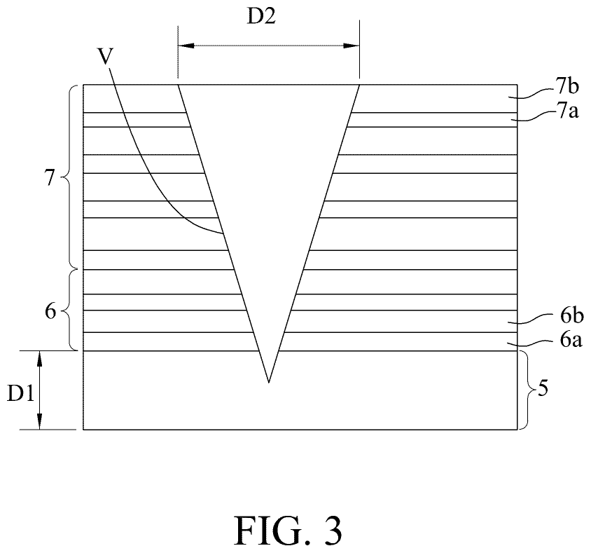

FIG. 4 is a concentration and ion intensity over depth chart showing relative elemental concentration and depth for selected layers of the first embodiments.

FIG. 5 is a schematic cross-sectional view illustrating a third embodiment according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

### First Embodiment

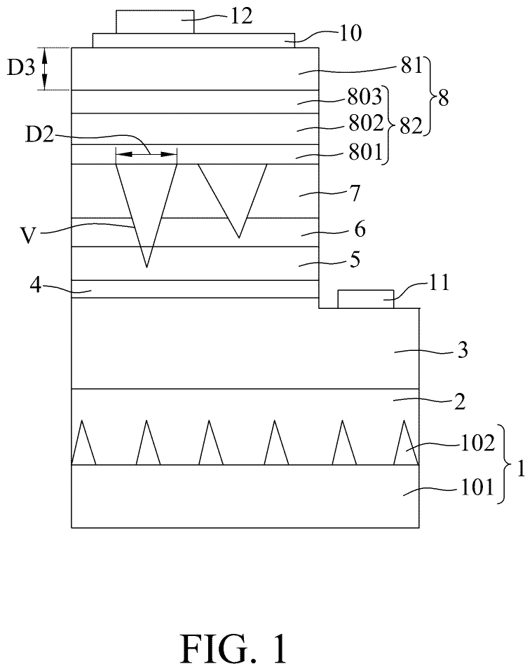

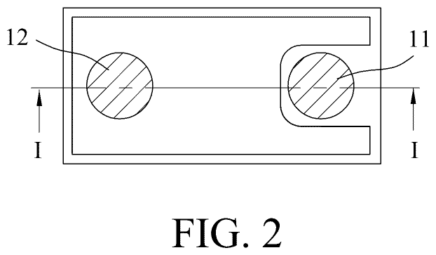

Referring to FIG. 1 and FIG. 2, FIG. 1 is a schematic cross-sectional view taken from line I-I in FIG. 2. Referring to FIG. 1, an embodiment of a light emitting diode according to the present disclosure includes a patterned substrate 1, a buffer layer 2 and an epitaxial semiconductor layer that are sequentially stacked in that order. In this embodiment, the light emitting diode is a nitride semiconductor light emitting diode (LED). The epitaxial semiconductor layer includes an N-type nitride layer 3, a lightly doped layer 4, a v-pit emergence layer 5, a strain adjustment layer 6, an active layer 7, and a P-type nitride layer 8 that are sequentially stacked in that order.

The patterned substrate 1 includes a substrate layer 101 and a plurality of surface structures 102. The substrate layer 101 includes a first surface, a second surface that is opposite to the first surface, and a side wall. The surface structures 102 are formed on the first surface of the substrate 101, spaced apart from each other, and periodically arranged to form a pattern on the first surface of the substrate layer 101. In some embodiments, the surface structures 102 are irregularly arranged and the pattern formed by the surface structures 102 of the first surface of the substrate layer 101 may be irregular. The epitaxial semiconductor layer is disposed on the patterned substrate 1. The substrate layer 101 may be an insulating substrate or may be a conductive substrate. The substrate layer 101 may serve as a growth substrate for epitaxial growth of the epitaxial semiconductor layer. The substrate layer 101 may be an insulating substrate such as a sapphire (Al₂O₃) substrate, or a spinal (MgAl₂O₄) substrate. The substrate layer 101 may also be a silicon carbide (SiC), a zinc sulfide (ZnS), a zinc oxide (ZnO), a silicon (Si), a gallium arsenide (GaAs), or a diamond substrate. In some embodiments, the substrate layer 101 may be an oxide substrate which facilitates lattice matching with nitride semiconductors such as lithium niobate (LiNbO₃) substrate, or a neodymium gallate (NdGaO₃) substrate. In this embodiment, the substrate layer 101 and the surface structures 102 are made of the same material which is sapphire.

The patterned substrate 1 has a thickness that ranges from 40 μm to 300 μm. In some embodiments, the patterned substrate 1 is relatively thicker and may range from 80 μm to 300 μm. In other embodiments, the patterned substrate is relatively thinner and may range from 40 μm to 80 μm. In some embodiments, the patterned substrate 1 may be even thinner and range from 40 μm to 60 μm.

The buffer layer 2 is formed between the patterned substrate 1 and the N-type nitride layer 3 in order to reduce lattice mismatch therebetween. The buffer layer 2 has a lattice constant that is between that of the N-type nitride layer 3 and the patterned substrate 1, and may be made of Alₓ₁In_{y1}Ga_{1-x1-y1}N, where 0≤x1≤1, and 0≤y1≤1. The buffer layer 2 may be an AlN layer, a GaN layer, an AlGaN layer, an AlInGaN layer, or an InGaN layer. The buffer layer 2 may be formed via metal organic chemical vapour deposition (MOCVD) or physical vapour deposition (PVD). In some embodiments, the buffer layer 2 includes a low temperature GaN nucleation layer with a thickness ranging from 25 μm to 40 μm, a high temperature GaN buffer layer with a thickness ranging from 0.2 μm to 1 μm, and a two-dimensional GaN layer with a thickness ranging from 1 μm to 2 μm.

The N-type nitride layer 3 is located between the buffer layer 2 and the active layer 7, and provides electrons. The N-type nitride layer 3 is doped with an N-type dopant to provide electrons. The N-type dopant may be Si, Ge, Sn, Se, or Te. In this embodiment, the N-type dopant is Si. The N-type nitride layer 3 has a thickness that ranges from 1 μm to 4 μm. The N-type nitride layer 3 may have a doping concentration that ranges from 1×10¹⁹/cm³ to 5×10¹⁹/cm³, and provide electrons for recombination with holes. The N-type nitride layer 3 may be a single layered structure or have a superlattice structure.

The lightly doped layer 4 is disposed between the N-type nitride layer 3 and the v-pit emergence layer 5. The lightly doped layer 4 provides increased horizontal current spreading, and increases anti-electrostatic protection for the light emitting diode. In some embodiments, the doping concentration for Si in the lightly doped layer 4 may range from 1×10¹⁷/cm³ to 5×10¹⁷/cm³. The lightly doped layer 4 may have a thickness that is greater than 0.01 μm. In some embodiments, the lightly doped layer 4 may have a thickness that ranges from 0.02 μm to 0.06 μm.

The epitaxial semiconductor layer further includes at least one v-pit (V). Referring to FIG. 1, the at least one v-pit (V) includes multiple v-pits (V). The v-pit emergence layer 5 is for the emergence of the v-pits (V). The emergence of the v-pits (V) begins in a layer above the N-type nitride layer 3.

The strain adjustment layer 6 is located between the v-pit emergence layer 5 and the active layer 7, is used to release strain generated from the formation of the N-type nitride layer 3, and increases the brightness of the light emitting diode. In this embodiment, the strain adjustment layer 6 has a superlattice structure made of alternating layers of wide band gap layers 6a and narrow band gap layers 6b. In this embodiment, the wide band gap layer 6a is Al_{y1}Ga_{1-y1}N and the narrow band gap layer 6b is Inₓ₁Ga₁₋ₓ₁N, where 0.04≤x1≤0.12 and 0≤y1≤0.06. The strain adjustment layer 6 has a superlattice structure with a period number that ranges from 3 to 8, and has a thickness that ranges from 20 nm to 80 nm. In this embodiment, the strain adjustment layer 6 has a period number of three.

In the prior art, there are techniques that can inject a certain amount of holes in a non-v-pit area (c-plane); however, the hole injection efficiency is poor, and thus limits enhancement of the photoelectric characteristics of the light emitting diode. In this embodiment, by adjusting conditions such as the thickness of the v-pit emergence layer 5, and the carbon doping concentration, large v-pits may be formed so that the effective c-plane area of the active layer 7 is reduced. This mitigates the problems of low hole injection efficiency at the c-plane, increases the hole injection efficiency at side walls of the v-pits (V), and improves the photoelectric characteristics of the light emitting diode.

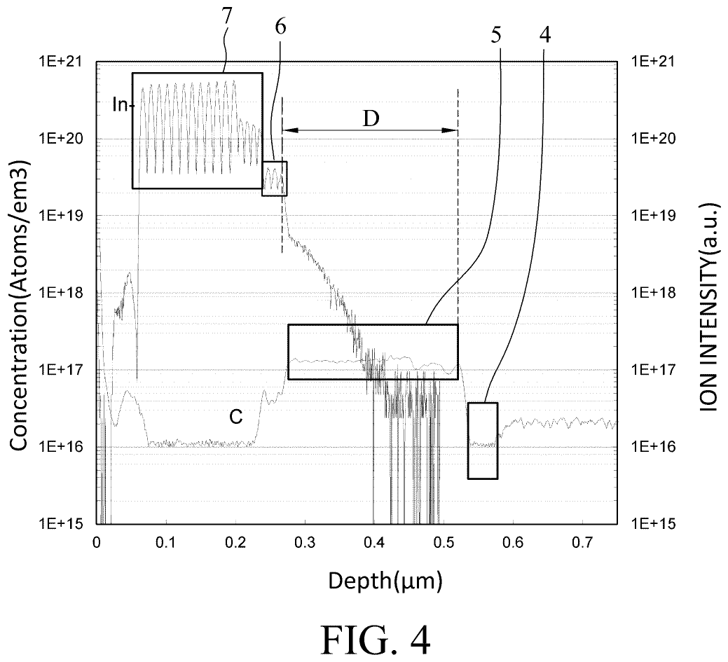

FIG. 4 shows an ion intensity and concentration over depth graph. Specifically, FIG. 4 shows carbon (C) doping concentration and indium (In) relative ion intensity according to depth. However, relative ion intensity of some elements of the light emitting diode are not shown in FIG. 4 such as nitrogen (N), gallium (Ga), aluminum (Al), silicon (Si). In this embodiment, the strain adjustment layer 6 has a periodic structure in the form of alternating layers of GaN/InGaN. The strain adjustment layer 6 has a period number of three. From FIG. 4 it may be observed that the indium (In) concentration in the strain adjustment layer is higher than that in the v-pit emergence layer 5. In other words, each of the v-pit emergence layer 5 and the strain adjustment layer 6 includes indium (In), and an indium (In) content of the strain adjustment layer 6 is higher than an indium (In) content of the v-pit emergence layer 5. The v-pit emergence layer (5) is doped with an N-type dopant at a doping concentration that ranges from 3×10¹⁷/cm³ to 7×10¹⁸/cm³. The v-pit emergence layer 5 may be doped with carbon (C) at a doping concentration that is no less than 7×10¹⁶/cm³. In some embodiments, the carbon (C) concentration in the v-pit emergence layer 5 is no less than 8×10¹⁶/cm³. The v-pit emergence layer 5 has a thickness that is no less than 230 nm. For example, in FIG. 4, a distance (D1) from a first peak of indium (In) in the strain adjustment layer 6 to a starting point of high carbon (C) doping concentration in the v-pit emergence layer 5 is greater than 230 nm. In other embodiments, (D1) may range from 240 nm to 400 nm so that a larger v-pit may be formed. In some embodiments, the v-pit emergence layer 5 includes In_{z1}Ga_{1-z1}N, wherein 0≤z1≤0.1. The v-pit emergence layer 5 may have a single layer structure or a multilayer structure. From FIG. 4 it may be observed that the N-type nitride layer 3 has a carbon doping concentration that is less than that of the v-pit emergence layer 5. Additionally, the lightly doped layer 4 has a carbon doping concentration that is less than that of the N-type nitride layer 3.

The active layer 7 is disposed between the N-type nitride layer 3 and the P-type nitride layer 8. The active layer 7 is where electron hole recombination takes place, and may be a multiple quantum well or a single quantum well. The active layer 7 may be made from different materials so that light of different wavelengths may be emitted from the active layer 7. The active layer 7 has a plurality of barrier layers (7b) and a plurality of well layers (7a) that are alternately stacked together from bottom up to form a periodic structure. In other words, in this embodiment, the active layer 7 is a multiple quantum well formed by alternating layers of the well layers (7a) made of Inₓ₂Ga₁₋ₓ₂N and the barrier layers (7b) made of Al_{y2}Ga_{1-y2}N, where 0.08≤x2≤0.18, and 0.02≤y2≤0.08. The barrier layers (7b) have a larger band gap than that of the well layers (7a). The semiconductor materials used to form the active layer 7 may be adjusted in order for the active layer 7 to emit light at different wavelengths. In some embodiments, the active layer 7 may be an InGaN/GaN multiple quantum well, and may have a period number that ranges from 5 to 15. Each of the InGaN layers may have a thickness that ranges from 2 nm to 4 nm, and each of the GaN layers may have a thickness that ranges from 3 nm to 15 nm. In some embodiments, the barrier layer (7b) may be doped with a small amount of aluminum (Al), and may be made of AlGaN.

The P-type nitride layer 8 includes a P-type GaN layer 81 and an AlₐIn_{b}Ga_{1-a-b}N layer 82 where 0≤a≤1, and 0≤b≤1. The AlₐIn_{b}Ga_{1-a-b}N layer 82 is disposed between the P-type GaN layer 81 and the active layer 7. The AlₐIn_{b}Ga_{1-a-b}N layer 82 includes a first sublayer 801, a second sublayer 802, and a third sublayer 803. An indium (In) content of the second sublayer 802 is higher than that of the first sublayer 801 and the third sublayer 803.

The first sublayer 801 of the AlₐIn_{b}Ga_{1-a-b}N layer 82 is formed on the active layer 7 to act as a barrier and prevent electron overflow. The first sublayer 801 may be made of one of AlN, AlGaN and AlInGaN, or a combination or combinations of the above. The first sublayer 801 has a band gap that is larger than the barrier layer (7b) of the active layer 7. In some embodiments, the first sublayer 801 has a band gap that is wider than that of the P-type GaN layer 81. In some embodiments, an Al concentration of the first sublayer 801 is higher than that of the barrier layer (7b) of the active layer 7. In some embodiments, the first sublayer 801 has a thickness that is greater than 1 nm in order to prevent electron overflow. However, since the thickness of the first sublayer 801 may influence hole injection efficiency, the thickness of the first sublayer 801 is designed to be less than 50 nm in this embodiment.

The second sublayer 802 is disposed between the first sublayer 801 and the third sublayer 803. An indium (In) concentration of the second sublayer 802 is higher than that of the first sublayer 801 and the third sublayer 803. The second sublayer 802 is a hole injection layer and has a thickness that ranges from 3 to 70 nm. In some embodiments, the second sublayer 802 has a thickness that is greater than 8 nm. In other embodiments, the second sublayer 802 may have a thickness that ranges from 10 nm to 50 nm. The second sublayer 802 may have a P-type doping concentration that is greater than 1×10¹⁹ Atoms/cm³. In some embodiments, the second sublayer 802 may have a P-type doping concentration that is greater than 5×10¹⁹ Atoms/cm³. For example, 1×10²⁰ Atoms/cm³ to 2×10²⁰ Atoms/cm³. By increasing the P-type doping concentration of the second sublayer 802 hole injection efficiency may be increased.

The third sublayer 803 is used to further limit overflow of electrons, and is disposed on the second sublayer 802. The third sublayer 803 has an aluminum (Al) concentration that is higher than that of the barrier layer (7b) of the active layer 7 and of the second sublayer 802. In some embodiments, the third sublayer 803 has a single layer structure. In other embodiments, the third sublayer 803 is an AlInGaN/GaN superlattice.

The P-type GaN layer 81 is disposed on the AlₐIn_{b}Ga_{1-a-b}N layer 82. The P-type GaN layer 81 is doped with a P-type material to provide holes. The P-type material may be Mg, Zn, Ca, Sr, Ba. In this embodiment, the P-type material is Mg. The P-type GaN layer 81 further includes an ohmic contact layer (not shown), is highly doped, for example with a doping concentration above 1×10²⁰ Atoms/cm³ for forming an ohmic contact with a P-type electrode of the light emitting diode. In this embodiment, the P-type GaN layer 81 has a thickness that is no less than 220 nm to fill the v-pit and mitigate pitting on the epitaxial semiconductor layer, thereby increasing the reliability of the light emitting diode. In some embodiments, the P-type GaN Layer 81 has a thickness that ranges from 220 nm to 240 nm.

A first electrode 11 and a second electrode 12 are respectively electrically connected to the N-type nitride layer 3 and the P-type nitride layer 8, directly or indirectly. In order to have the first electrode 11 and the second electrode 12 formed on the same side of the N-type nitride layer 3 and the P-type nitride layer 8, the P-type nitride layer 8 may be formed on the N-type nitride layer 3, and the N-type nitride layer 3 may be partially exposed from the P-type nitride layer 8. In other embodiments, the N-type nitride layer 3 may be formed on the P-type nitride layer 8, the P-type nitride layer 8 may be partially exposed. When the active layer 7 and the P-type nitride layer 8 are formed on the N-type nitride layer 3, the N-type nitride layer 3 may be partially exposed by removing portions of the active layer 7 and the P-type nitride layer 8. At least one through hole (not shown) may be formed which passes through the P-type nitride layer 8 and the active layer 7 to expose the N-type nitride layer 3. A side wall (not shown) of the through hole is defined by boundaries of the active layer 7 and the P-type nitride layer 8. In other embodiments, the epitaxial semiconductor layer may include one or more mesas. The mesa may be disposed on the N-type nitride layer 3 and formed from the active layer 7 and the P-type nitride layer 8. In this embodiment, there is one mesa formed from the active layer 7 and the P-type nitride layer 8.

The light emitting diode includes a transparent conducting layer 10 located on the P-type nitride layer 8. The transparent conducting layer 10 forms an ohmic contact with the P-type nitride layer 8. The transparent conducting layer 10 is made of a transparent and conductive material such as a conductive oxide material and is located on the light emitting side of the light emitting diode. The conductive oxide material may be an oxide of Zn, In, Sn, or Mg. In particular, examples of the transparent conducting layer 10 are ZnO, In₂O₃, SnO₂, indium tin oxide (ITO), indium zinc oxide (IZO), and gallium doped zinc oxide (GZO). Conductive oxide materials such as ITO are suitable because they have high transparency, for example over 60%, 70%, 75%, or 80%, and exhibit high electrical conductivity.

In this embodiment, the first electrode 11 is an N-type electrode, and the second electrode 12 is a P-type electrode. The second electrode 12 is electrically connected with the transparent conductive layer 10 and the P-type nitride layer 8.

In some embodiment, when viewed from above, the first electrode 11 or the second electrode 12 may be disposed in an interior of the nitride light emitting diode. In other words, the first electrode 11 is surrounded by the N-type nitride layer 3, or the second electrode 12 is surrounded by the P-type nitride layer 8. Thus, the first electrode 11 or the second electrode 12 may be disposed along an entire periphery of the light emitting diode. Better current spreading may be achieved with this design. In some embodiments, the first electrode 11 or the second electrode 12 may not be completely surrounded by the N-type nitride layer 3 or the P-type nitride layer 8. In some embodiments, the first electrode 11 may be partially or completely surrounded by the second electrode 12. In other embodiments, the second electrode 12 may be partially or completely surrounded by the first electrode 11. In order to ensure efficient active area of the N-type nitride layer 3, the N-type electrode may be partially or completely surrounded by the P-type electrode.

The first electrode 11 and the second electrode 12 are electrode pads for external electrical connection to provide power to the light emitting diode. The first electrode 11 and the second electrode 12 are disposed respectively at two opposite sides of the epitaxial semiconductor layer. When viewed form above the light emitting diode, the first electrode 11 and the second electrode 12 may each have a shape that is most suitable for the size and layout of the light emitting diode. In some embodiments, the first electrode 11 and the second electrode 12 may be electrode pads with a round shape, or a polygonal shape. In some embodiments, the first electrode 11 and the second electrode 12, when viewed from above the light emitting diode, may each have a roughly circular shape that has a diameter ranging from 70 μm to 150 μm. The first electrode 11 and the second electrode 12 may have the same or different shape and size.

In this embodiment, a thickness of the v-pit emergence layer 5 and the amount of carbon (C) doping may be adjusted to form a large V-pit which may improve hole injection along a side wall of the V-pit, thereby decreasing the operating voltage of the light emitting diode and improving light emission efficiency. In this embodiment, the v-pit (V) has an opening that is located at a topmost one of the barrier layers of the active layer 7, and has a width that is greater than 260 nm. By having a large v-pit (V), a droop effect may be decreased under high operating current. In a test that was conducted with the light emitting diode according to the disclosure, the light emitting diode had dimensions of 560×890 μm and was individually packaged. An external quantum efficiency (EQE) test was conducted with current density (J) as a variable. Results show that EQE was raised by 3.5% (from 76.5% to 80%) and operating voltage VF₁ was decreased by 0.02V under a current density (J) of 24 A/cm². When the current density (J) was raised to 80.7 A/cm² for testing droop effect, EQE was raised by 5% (from 83% to 88%).

### Second Embodiment

A second embodiment of the disclosure is a method of making the light emitting diode of the first embodiment.

First, a patterned substrate 1 is provided. In the second embodiment, the patterned substrate is a sapphire substrate; in order to minimize lattice mismatch between the patterned substrate 1 and an N-type nitride layer 3, a buffer layer 2 is then formed on the patterned substrate 1. In this embodiment, the buffer layer 2 includes a low temperature nucleation GaN layer with a thickness that ranges from 25 nm to 40 nm, a high temperature GaN buffer layer with a thickness ranging from 0.2 μm to 1 μm, and 2-dimensional GaN layer with a thickness ranging from 1 μm to 2 μm.

Afterwards, the N-type nitride layer 3 is formed on the buffer layer 2 and has a thickness ranging from 1 μm to 4 μm and a doping concentration that ranges from 1×10¹⁹/cm³ to 5×10¹⁹/cm³. The N-type nitride layer 3 may be a single layered structure or a superlattice. Next, a lightly doped layer 4 is formed on the N-type nitride layer 3. The lightly doped layer 4 has a doping concentration that ranges from 1×10¹⁷/cm³ to 5×10¹⁷/cm³.

Next, a v-pit emergence layer 5 is formed on the lightly doped layer 4. The v-pit emergence layer 5 has a thickness that is no less than 230 nm. In some embodiments, the v-pit emergence layer 5 has a thickness that ranges from 240 nm to 400 nm. The v-pit emergence layer 5 has a carbon (C) doping concentration that is no less than 7×10¹⁶/cm³.

Next, a strain adjustment layer 6 is formed on the v-pit emergence layer 5. In this embodiment, the strain adjustment layer 6 is a superlattice made of alternating layers of Inₓ₁Ga₁₋ₓ₁N and Ga_{1-y1}N. In other embodiments the strain adjustment layer 6 may be a single layered structure.

Next, an active layer 7 is formed on the strain adjustment layer 6. In this embodiment, the active layer 7 is a multiple quantum well having a plurality of barrier layers (7b) and a plurality of well layer (7a) and has a periodic structure. In this embodiment, the active layer 7 has a period number that ranges from 5 to 15, and is formed from alternating layers of InGaN and GaN. More specifically, the InGaN layer within each period has a thickness that ranges from 2 nm to 4 nm, and the GaN layer within each period has a thickness that ranges from 3 nm to 15 nm. In some embodiments, the barrier layers (7b) of the active layer 7 may be lightly doped with aluminum (Al). The barrier layers (7b) may be made of AlGaN.

Next, an AlₐIn_{b}Ga_{1-a-b}N layer 82 is formed on the active layer 7. The AlₐIn_{b}Ga_{1-a-b}N layer 82 includes a first sublayer 801, a second sublayer 802, and a third sublayer 803. In this embodiment, an indium (In) content of the second sublayer 802 is higher than that of the first sublayer 801 and the third sublayer 803, and an aluminum (Al) content of the first sublayer 801 and the third sublayer 803 is higher than an aluminum content of the barrier layers (7b) of the active layer 7.

Next, a P-type GaN layer 81 is formed on the AlₐIn_{b}Ga_{1-a-b}N layer 82. In this embodiment, the P-type GaN layer 81 has a thickness that is greater than 220 nm. In some embodiments, the P-type GaN layer 81 has a thickness that is greater than 240 nm. The P-type GaN layer 81 may include a P-type ohmic contact layer (not shown) that is highly doped (for example, with a doping concentration of more than 1×10²⁰ Atoms/cm³), and that forms an ohmic contact with a second electrode 12 (P-type electrode). The P-type GaN layer 81 and the AlₐIn_{b}Ga_{1-a-b}N layer 82 together forms a P-type nitride layer 8.

Next, a transparent conductive layer 10 is formed on the P-type GaN layer 81. The transparent conductive layer 10 may form an ohmic contact with the P-type nitride layer 8. The transparent conductive layer 10 includes an oxide of Zn, In, Sn, or Mg. For example ZnO, In₂O₃, SnO₂, indium tin oxide (ITO), indium zinc oxide (IZO), or gallium doped zinc oxide (GZO). In this embodiment, the transparent conductive layer 10 is ITO.

Next, a portion of each of the transparent conductive layer 10, the P-type GaN layer 81, AlₐIn_{b}Ga_{1-a-b}N layer 82, the active layer 7, the strain adjustment layer 6, the v-pit emergence layer 5, and the lightly doped layer 4 is etched away to expose a surface of the N-type nitride layer 3. Afterwards, a first electrode 11 and a second electrode 12 are respectively formed on the N-type nitride layer 3 and the transparent conductive layer 10.

By adjusting the carbon (C) doping concentration and the thickness of the v-pit emergence layer 5, a larger v-pit (V) may be formed that has increased hole injection at the side wall of the v-pit (V). This allows the operating voltage of the light-emitting diode to be decreased, while increasing the light emission efficiency thereof and decreasing the droop effect. A thickness of the P-type nitride layer 8 may be adjusted to fill the v-pit (V) and mitigate pitting on a surface of the epitaxial semiconductor layer, thereby increasing the reliability of the light emitting diode.

### Third Embodiment

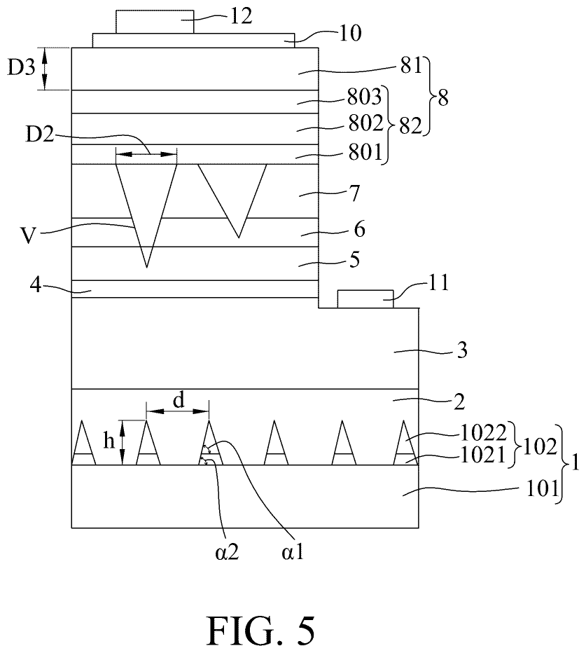

Referring to FIG. 5, a third embodiment of the present disclosure is a light emitting diode similar to the first embodiment. However, in the first embodiment, the substrate layer 101 and the surface structures 102 are made of the same material which is sapphire, whereas, in this embodiment, each of the surface structures 102 has a first portion 1021 that is disposed on the first surface of the substrate layer 101, and a second portion 1022 that is disposed on the first portion 1021. The first portions 1021 of the surface structures 102 may be made of the same material as the substrate layer 101, or a different material. In this embodiment, the first portions 1021 are made of the same material as the substrate layer 101 which is sapphire. The second portions 1022 of the surface structures 102 are made of a material different from that of the first portions 1021 and the substrate layer 101. In some embodiments, the first portions 1021 may be made of a material that is different from that of the substrate layer 101, and the substrate layer 101 may have a refraction index that is greater than that of the first portions 1021.

The second portions 1022 may be made of a material that has a low refraction index, but the use of this material may cause the second portion 1022 to have a surface that is inhospitable for epitaxial growth. However, when the second portion 1022 has a refraction index that is less than that of the first portion 1021, and that of the epitaxial semiconductor layer 101, total internal reflection of light emitted from the epitaxial semiconductor layer may be achieved in order to reflect light toward the light exiting surface so that light extraction efficiency may be increased. The second portions 1022 may be made of one of materials such as SiO₂, SiN₄, ZnO₂, Si, Sic, GaAs, Ti₃O₅, and TiO₂, or a combination of the materials. In this embodiment, the second portions 1022 are made of SiO₂.

Each first portion 1021 has a side wall that is inclined at a first angle (α1) relative to a top surface of the substrate layer 101. Each second portion 1022 has a side wall that is inclined at a second angle (α2) relative to a top surface of said first portion 1021. The first angle (α1) may be the same or different from the second angle (α2). In this embodiment, the first angle (α1) is the same as the second angle (α2). The surface structure(s) 102 has a gradually decreasing diameter, and forms a conical shape. In other words, in this case, the first angle (α1) and the second angle (α2) are the same. In some embodiments, the first angle (α1) is different from the second angle (α2); for example, the first angle (α1) may be larger than the second angle (α2).

Referring to FIG. 5, in this embodiment, each of the surface structures 102 has a height that ranges from 1.4 μm to 2.4 μm relative to the top surface of the substrate layer 101. A pitch (d) between two adjacent patterned structures 102 ranges from 2.2 μm to 3.5 μm.

In this embodiment, the epitaxial semiconductor layer is formed on the patterned substrate 1 which reduces the amount of mismatch for the epitaxial semiconductor layer and increases the quality of its crystal lattice. Furthermore, by having the first portion 1021 and the second portion 1022 of the surface structure 102 being made from different materials, the second portion 1022 may be designed to have a smaller refraction index than either the first portion 1021 or the epitaxial semiconductor layer. When light emitted from the epitaxial semiconductor layer reaches the second portion 1022, total internal reflection may occur to reflect light towards the light exiting surface of the light emitting diode which increases light extraction efficiency. Additionally, thickness and doping concentration of the v-pit emergence layer 5 may be adjusted to increase the size of the v-pits (V), thereby increasing hole injection at the side walls of the v-pits (V), decreasing the operating voltage of the light emitting diode, and improving light extraction efficiency of the light emitting diode. Furthermore, with this design, a droop effect under large current may be decreased. Besides, the thickness of the P-type GaN layer 81 may be adjusted to fill the v-pits (V) to thereby mitigate pitting on the surface of the epitaxial semiconductor layer. This increases the reliability of the light emitting diode.

According to another aspect of the disclosure a light emitting device is disclosed. The light emitting device includes the light emitting diode according to the first embodiment or the third embodiment of the present disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light emitting diode comprising:
an epitaxial semiconductor layer including an N-type nitride layer, a v-pit emergence layer, a strain adjustment layer, an active layer, and a P-type nitride layer that are sequentially stacked in that order, said active layer having a plurality of barrier layers and a plurality of well layers that are alternately stacked together from bottom up, said wells layers having a smaller band gap than that of said barrier layers, said semiconductor layer further including at least one v-pit;
wherein each of said v-pit emergence layer and said strain adjustment layer includes indium (In), and an indium (In) content of said strain adjustment layer is higher than an indium (In) content of said v-pit emergence layer;
wherein said at least one v-pit has an opening that is located at a topmost one of said barrier layers of said active layer, and that has a width that is greater than 260 nm; and
wherein said v-pit emergence layer is doped with carbon (C) at a doping concentration that is no less than 7×10¹⁶/cm³.

2. The light emitting diode as claimed in claim 1, wherein said v-pit emergence layer has a thickness that is no less than 230 nm.

3. The light emitting diode as claimed in claim 1, wherein said v-pit emergence layer is doped with an N-type dopant at a doping concentration that ranges from 3×10¹⁷/cm³ to 7×10¹⁸/cm³.

4. The light emitting diode as claimed in claim 1, wherein said v-pit emergence layer has a single layer structure or a multilayer structure.

5. The light emitting diode as claimed in claim 1, wherein said v-pit emergence layer includes In_{z1}Ga_{1-z1}N, wherein 0≤z1≤0.1.

6. The light emitting diode as claimed in claim 1, wherein said strain adjustment layer is a superlattice made of alternating layers of Inₓ₁Ga₁₋ₓ₁N/Al_{y1}Ga_{1-y1}N, wherein 0≤x1≤1, 0≤y1≤1.

7. The light emitting diode as claimed in claim 6, wherein said strain adjustment layer has a period number that ranges from 3 to 8, and has a thickness that ranges from 20 nm to 80 nm.

8. The light emitting diode as claimed in claim 1, wherein said active layer is a multiple quantum well formed by alternating layers of said well layers made of Inₓ₂Ga₁₋ₓ₂N, and said barrier layers made of Al_{y2}Ga_{1-y2}N, wherein 0≤x2≤1, 0≤y2≤1.

9. The light emitting diode as claimed in claim 8, wherein said active layer has a period number that ranges from 5 to 15.

10. The light emitting diode as claimed in claim 1, wherein said P-type nitride layer has a flat top surface.

11. The light emitting diode as claimed in claim 1, wherein said P-type nitride layer includes a P-type GaN layer and an AlₐIn_{b}Ga_{1-a-b}N layer where 0<a≤1 and 0≤b<1, said AlₐIn_{b}Ga_{1-a-b}N layer being disposed between said P-type GaN layer and said active layer.

12. The light emitting diode as claimed in claim 11, wherein said P-type GaN layer has a thickness that is no less than 220 nm.

13. The light emitting diode claimed in claim 11, wherein:
said AlₐIn_{b}Ga_{1-a-b}N layer includes a first sublayer, a second sublayer, and a third sublayer;
an Indium (In) content of said second sublayer being higher than that of said first sublayer and said third sublayer.

14. A light emitting diode comprising:
an epitaxial semiconductor layer including an N-type nitride layer, a v-pit emergence layer, a strain adjustment layer, an active layer, and a P-type nitride layer that are sequentially stacked in that order, said active layer having a plurality of barrier layers and a plurality of well layers that are alternately stacked together from bottom up, said wells layers having a smaller band gap than that of said barrier layers, said semiconductor layer including at least one v-pit;
wherein each of said v-pit emergence layer and said strain adjustment layer includes indium (In), and an indium (In) content of said strain adjustment layer is higher than an indium (In) content of said V-pit emergence layer;
wherein said at least one v-pit has an opening that is located at a topmost one of said barrier layers of said active layer, and that has a width greater than 260 nm; and
wherein a distance (D1) from a first peak of indium (In) in said strain adjustment layer to a starting point of high carbon (C) doping concentration in said v-pit emergence layer is greater than or equal to 230 nm.

15. The light emitting diode as claimed in claim 14, wherein said v-pit emergence layer is doped with carbon (C) at a doping concentration that is no less than 7×10¹⁶/cm³.

16. The light emitting diode as claimed in claim 14, wherein:
said N-type nitride layer has a carbon doping concentration that is less than that of said v-pit emergence layer;
said epitaxial semiconductor layer further including a lightly doped layer disposed between said N-type nitride layer and said v-pit emergence layer; and
said lightly doped layer has a carbon doping concentration that is less than that of said N-type nitride layer.

17. The light emitting diode as claimed in claim 14, wherein said v-pit emergence layer includes In_{z1}Ga_{1-z1}N, wherein 0≤z1≤0.1.

18. The light emitting diode as claimed in claim 14, wherein said v-pit emergence layer is doped with an N-type dopant at a doping concentration that ranges from 3×10¹⁷/cm³ to 7×10¹⁸/cm³.

19. The light emitting diode as claimed in claim 14 further comprising a patterned substrate, said epitaxial semiconductor layer is disposed on said patterned substrate, said patterned substrate having a plurality of patterned structures that are periodically arranged on an upper surface of said patterned substrate.

20. A light emitting device comprising the light emitting diode as claimed in claim 1.
